(19) United States
(12) Patent Application Publication
(10) Pub. No.: US 2026/0126077 A1
(43) Pub. Date: May 7, 2026

(54) MOVING STRUCTURE

(71) Applicant: FIVETECH TECHNOLOGY INC., New Taipei City (TW)

(72) Inventors: TING-JUI WANG, New Taipei City (TW); CHIA-CHING LIAO, New Taipei City (TW)

(73) Assignee: FIVETECH TECHNOLOGY INC., New Taipei City (TW)

(21) Appl. No.: 19/359,727

(22) Filed: Oct. 16, 2025

(30) Foreign Application Priority Data
Nov. 7, 2024 (TW) 113142716

(51) Int. Cl. F16C 11/04

(52) U.S. Cl. CPC F16C 11/04

(57) ABSTRACT

The present disclosure provides a moving structure. The moving structure includes an operating member, a transmission member, and a moving member. The operating member is movably arranged on a base body. The transmission member is movably arranged on the base body and is movably connected to an end of the operating member. The moving member is movably arranged on the base body, and one end is movably connected to the transmission member. An other end of the moving member is configured to abut and push to be snap-fitted to or unfastened from a corresponding object, or the moving member abuts and pushes the corresponding object to drive the object to move, or the moving member abuts and pushes the corresponding object to drive the object to move in a lever-based labor-saving manner.

### CROSS-REFERENCE TO RELATED APPLICATION

This non-provisional application claims priority under 35 U.S.C. § 119(a) on Patent Application No(s). 113142716 filed in Taiwan, R.O.C. on Nov. 7, 2024, the entire contents of which are hereby incorporated by reference.

### BACKGROUND OF THE INVENTION

### FIELD OF THE INVENTION

The present disclosure relates to a moving structure, and in particular, to a moving structure that may be used for repeatedly and rapidly engaging and disengaging at least two objects.

### DESCRIPTION OF THE RELATED ART

Generally, during engagement of at least one object, locking is usually performed through a screw, to engage with the object.

In the foregoing fixing manner, although at least one object may be fixed and engaged in a manner of being not easy to be separated, in addition to causing a case of being not easy to be assembled, at least the object is not easy to be disassembled due to the fixing and engaging manner of the screw.

In view of the foregoing conventional technology, the inventor develops a moving structure to effectively improve conventional defects.

### BRIEF SUMMARY OF THE INVENTION

According to the moving structure of the present disclosure, a base body may be assembled with an object, and a force is applied to an operating member to coordinate with a transmission member to drive a moving member to abut and push to be snap-fitted to or unfastened from a corresponding object, to complete rapid engagement and disengagement of at least two objects, thereby achieving an effect of repeated rapid engagement and disengagement.

To achieve the foregoing objective and another objective, the present disclosure provides a moving structure, including an operating member, a transmission member, and a moving member. The operating member is movably arranged on a base body. The transmission member is movably arranged on the base body and is movably connected to an end of the operating member. The moving member is movably arranged on the base body, and one end is movably connected to the transmission member. An other end of the moving member is configured to abut and push to be snap-fitted to or unfastened from a corresponding object, or the moving member is configured to abut and push the corresponding object to drive the object to move, or the moving member is configured to abut and push the corresponding object to drive the object to move in a lever-based manner.

Optionally, the operating member includes a force application portion, a first engaging portion, and a first joining portion. The first engaging portion is arranged on an end of the force application portion. The first engaging portion is movably connected to the transmission member in an engaging manner. The first joining portion is movably arranged on the first engaging portion and assembled to the base body.

Optionally, the first engaging portion has a plurality of first teeth. The first engaging portion is movably connected to the transmission member in an engaging manner through each of the first teeth.

Optionally, the operating member is provided with a fixing portion, and the fixing portion is snap-fitted to or unfastened from a limiting portion of the object.

Optionally, the fixing portion is movably assembled to the operating member through a bolt.

Optionally, an elastic assembly is arranged between the fixing portion and the operating member.

Optionally, the transmission member includes a second engaging portion and a second joining portion. The second joining portion is movably arranged on the second engaging portion and assembled to the base body. The second engaging portion is movably connected to the operating member and the moving member in an engaging manner.

Optionally, the second engaging portion has a plurality of second teeth. The second engaging portion is movably connected to the operating member and the moving member in an engaging manner through each of the second teeth.

Optionally, the moving member includes a third engaging portion, a third joining portion, a first abutting portion, a second abutting portion, and a snap-fit portion. The third engaging portion is arranged on an end of the moving member. The third engaging portion is movably connected to the transmission member in an engaging manner. The third joining portion is movably arranged on the third engaging portion and assembled to the base body. The first abutting portion and the second abutting portion are correspondingly arranged on an other end of the moving member. The snap-fit portion is located between the first abutting portion and the second abutting portion.

Optionally, the third engaging portion has a plurality of third teeth. The third engaging portion is movably connected to the transmission member in an engaging manner through each of the third teeth.

Optionally, the corresponding object or the object is a server casing, a casing, a mainboard, a server rack, a rack, a radiator, a sliding rail, a chip, a connector, a server, or a computer.

Optionally, the moving member includes a third engaging portion, a third joining portion, a first abutting portion, and a second abutting portion. The third engaging portion is arranged on the moving member. The third engaging portion is movably connected to the transmission member in an engaging manner to drive the moving member to move through gears, so that the first abutting portion or the second abutting portion abuts against the corresponding object to drive the object to move.

Optionally, the object is a server, a computer, or a printed circuit board that is horizontally arranged, or the corresponding object is a casing, a cabinet, or a column that is longitudinally arranged, so that the moving structure drives the object to move forward and backward, or to move forward and backward in a horizontal position.

Optionally, the object is a server, a computer, or a printed circuit board that is longitudinally arranged, or the corresponding object is a casing, a cabinet, or a column that is longitudinally arranged, so that the moving structure drives the object to move forward and backward, or to move forward and backward in a horizontal position.

Optionally, the moving structure is configured to separate or connect a water cooling joint, a connector, or a coolant pipeline.

The present disclosure provides another moving structure. The moving structure includes an operating member and a moving member. The operating member is movably arranged on the base body. The moving member is movably arranged on the base body and movably connected to the operating member, or configured to abut and push to be snap-fitted to or unfastened from a corresponding object, or configured to abut and push the corresponding object to drive the object to move, or configured to abut and push the corresponding object to drive the object to move through leverage.

The present disclosure provides a moving method for another moving structure. A moving structure is provided. The moving structure includes an operating member, a transmission member, and a moving member. The operating member is movably arranged on the base body. The transmission member is movably arranged on the base body and is movably connected to an end of the operating member. The moving member is movably arranged on the base body and movably connected to the transmission member, or configured to abut and push to be snap-fitted to or unfastened from a corresponding object, or configured to abut and push the corresponding object to drive the object to move, or configured to abut and push the corresponding object to drive the object to move through leverage. Alternatively, the operating member includes a force application portion, a first engaging portion, or a first joining portion, or the first engaging portion is arranged on the force application portion, or the first engaging portion is movably connected to the transmission member in an engaging manner, or the first joining portion is movably arranged on the first engaging portion or assembled to the base body. Alternatively, the first engaging portion has a plurality of first teeth, or the first engaging portion is movably connected to the transmission member in an engaging manner through each of the first teeth. Alternatively, the operating member is provided with a fixing portion, and the fixing portion is snap-fitted to or unfastened from a limiting portion of the object. Alternatively, the fixing portion is movably assembled to the operating member through a bolt, or an elastic assembly is arranged between the fixing portion and the operating member.

The present disclosure provides a moving method for another moving structure. A moving structure is provided. The moving structure includes an operating member, a transmission member, and a moving member. The operating member is movably arranged on the base body. The transmission member is movably arranged on the base body and is movably connected to an end of the operating member. The moving member is movably arranged on the base body and movably connected to the transmission member, or configured to abut and push to be snap-fitted to or unfastened from a corresponding object, or configured to abut and push the corresponding object to drive the object to move, or configured to abut and push the corresponding object to drive the object to move through leverage. Alternatively, the transmission member includes a second engaging portion or a second joining portion, or the second joining portion is movably arranged on the second engaging portion or assembled to the base body, or the second engaging portion is movably connected to the operating member and a fastener in an engaging manner. Alternatively, the second engaging portion has a plurality of second teeth, or the second engaging portion is movably connected to the operating member and the fastener in an engaging manner through each of the second teeth.

The present disclosure provides a moving method for another moving structure. A moving structure is provided. The moving structure includes an operating member, a transmission member, and a moving member. The operating member is movably arranged on the base body. The transmission member is movably arranged on the base body and is movably connected to an end of the operating member. The moving member is movably arranged on the base body and movably connected to the transmission member, or configured to abut and push to be snap-fitted to or unfastened from a corresponding object, or configured to abut and push the corresponding object to drive the object to move, or configured to abut and push the corresponding object to drive the object to move through leverage. The fastener includes a third engaging portion, a third joining portion, a first abutting portion, a second abutting portion, or a snap-fit portion, or the third engaging portion is arranged on the fastener, or the third engaging portion is movably connected to the transmission member in an engaging manner, or the third joining portion is movably arranged on the third engaging portion or assembled to the base body, or the first abutting portion and the second abutting portion are correspondingly arranged on an other end of the fastener, or the snap-fit portion is located between the first abutting portion and the second abutting portion. Alternatively, the third engaging portion has a plurality of third teeth, or the third engaging portion is movably connected to the transmission member in an engaging manner through each of the third teeth. Alternatively, the moving member includes a third engaging portion, a third joining portion, a first abutting portion, and a second abutting portion. The third engaging portion is arranged on the moving member, and the third engaging portion is movably connected to the transmission member in an engaging manner to drive the moving member to move through gears, so that the first abutting portion or the second abutting portion abuts against the corresponding object to drive the object to move.

The present disclosure provides a moving method for another moving structure. A moving structure is provided. The moving structure includes an operating member and a moving member. The operating member is movably arranged on a base body. The operating member is movably arranged on a base body. The moving member is movably arranged on the base body and movably connected to the transmission member, or configured to abut and push to be snap-fitted to or unfastened from a corresponding object, or configured to abut and push the corresponding object to drive the object to move, or configured to abut and push the corresponding object to drive the object to move through leverage. The object is a server, a computer, or a printed circuit board that is longitudinally arranged, or the corresponding object is a casing, a cabinet, or a column that is longitudinally arranged, so that the moving structure drives the object to move forward and backward, or to move forward and backward in a horizontal position. Alternatively, the object is a server, a computer, or a printed circuit board that is longitudinally arranged, or the corresponding object is a casing, a cabinet, or a column that is longitudinally arranged, so that the moving structure drives the object to move forward and backward, or to move forward and backward in a horizontal position. Alternatively, the moving structure is configured to separate or connect a water cooling joint, a connector, or a coolant pipeline.

The present disclosure provides a moving method for another moving structure. A moving structure is provided. The moving structure includes an operating member, a transmission member, and a moving member. The operating member is movably arranged on a base body. The transmission member is movably arranged on the base body and is movably connected to the operating member. The moving member is movably arranged on the base body and movably connected to the transmission member, or configured to abut and push to be snap-fitted to or unfastened from a corresponding object, or configured to abut and push the corresponding object to drive the object to move, or configured to abut and push the corresponding object to drive the object to move through leverage. The object is a server, a computer, or a printed circuit board that is longitudinally arranged, or the corresponding object is a casing, a cabinet, or a column that is longitudinally arranged, so that the moving structure drives the object to move forward and backward, or to move forward and backward in a horizontal position. Alternatively, the object is a server, a computer, or a printed circuit board that is longitudinally arranged, or the corresponding object is a casing, a cabinet, or a column that is longitudinally arranged, so that the moving structure drives the object to move forward and backward, or to move forward and backward in a horizontal position. Alternatively, the moving structure is configured to separate or connect a water cooling joint, a connector, or a coolant pipeline.

### BRIEF DESCRIPTION OF THE DRAWINGS

To describe technical solutions in embodiments of the present disclosure or in the related art more clearly, the accompanying drawings required for describing the embodiments or existing technologies are briefly described below. Apparently, the accompanying drawings in the following description show some embodiments of the present disclosure, and a person of ordinary skill in the art may still derive other drawings from these accompanying drawings without creative efforts.

FIG. 1 is a schematic exploded view according to a preferred specific embodiment of the present disclosure.

FIG. 2 is a schematic diagram I of an appearance according to a preferred specific embodiment of the present disclosure.

FIG. 3 is a schematic diagram II of an appearance according to a preferred specific embodiment of the present disclosure.

FIG. 4 is a schematic diagram III of an appearance according to a preferred specific embodiment of the present disclosure.

FIG. 5 is a schematic top view according to a preferred specific embodiment of the present disclosure.

FIG. 6 is a schematic side view according to a preferred specific embodiment of the present disclosure.

FIG. 7 is a schematic diagram I of a usage state according to a preferred specific embodiment of the present disclosure.

FIG. 8 is a schematic diagram II of a usage state according to a preferred specific embodiment of the present disclosure.

FIG. 9 is a schematic diagram III of a usage state according to a preferred specific embodiment of the present disclosure.

FIG. 10 is a schematic exploded view according to another preferred specific embodiment of the present disclosure.

FIG. 11 is a schematic exploded view according to another preferred specific embodiment of the present disclosure.

FIG. 12 is another schematic use diagram according to a preferred specific embodiment of the present disclosure.

### DETAILED DESCRIPTION OF THE INVENTION

A fluid bonding structure in embodiments of the present disclosure is described below with reference to the accompanying drawings.

The foregoing and other technical contents, features, and effects of the present disclosure are clearly presented in the following detailed description of preferred embodiments with reference to drawings. It should be noted that directional terms such as "above", "below", "left", "right", "front", or "back" in the following embodiments are directions in the drawings. Therefore, the directional terms that are used are used for describing rather than limiting the present disclosure. In addition, in the following embodiments, identical or similar assemblies are denoted by identical or similar reference numerals.

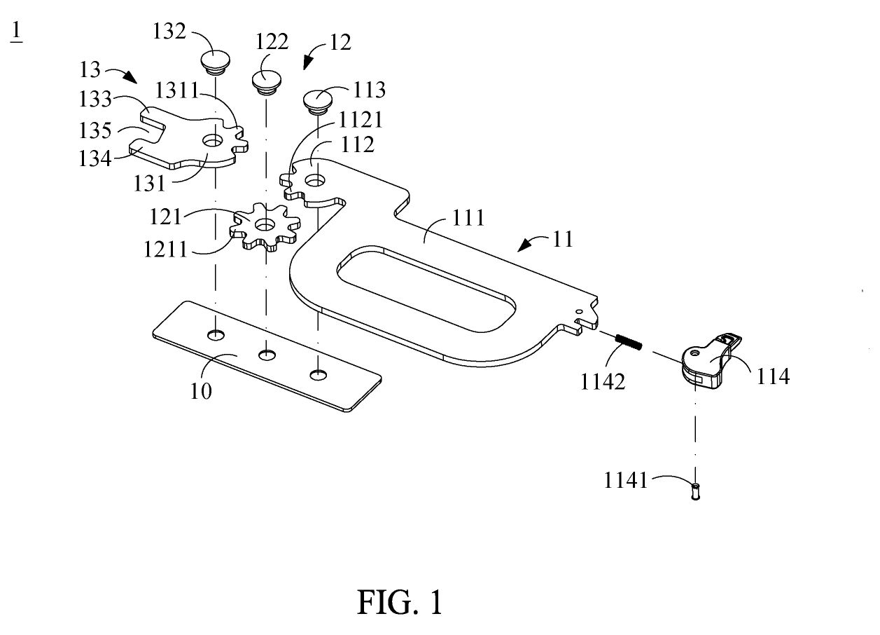

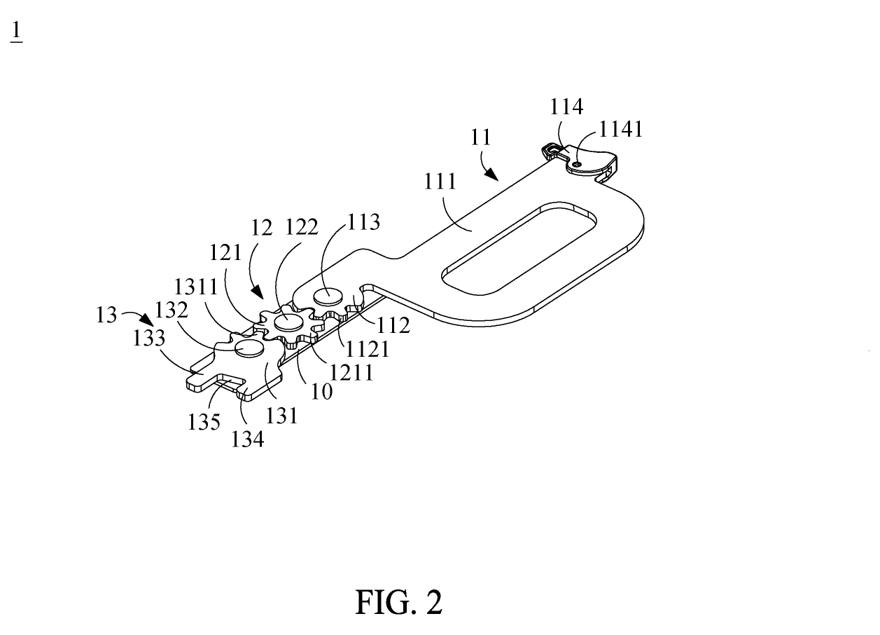

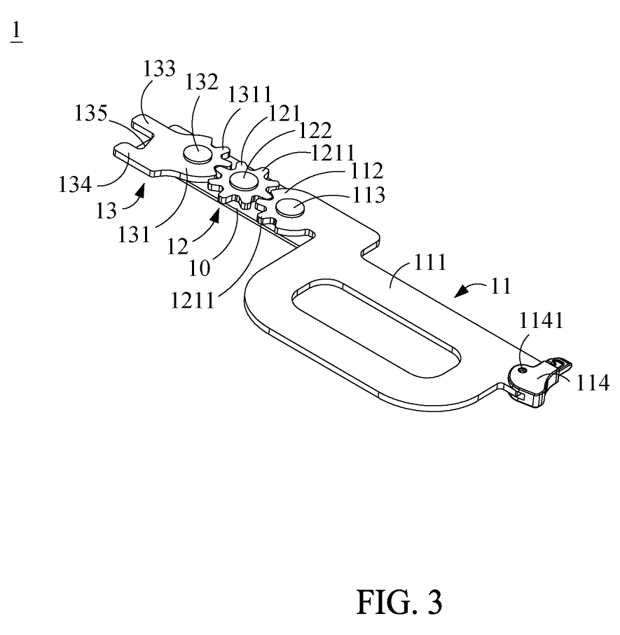

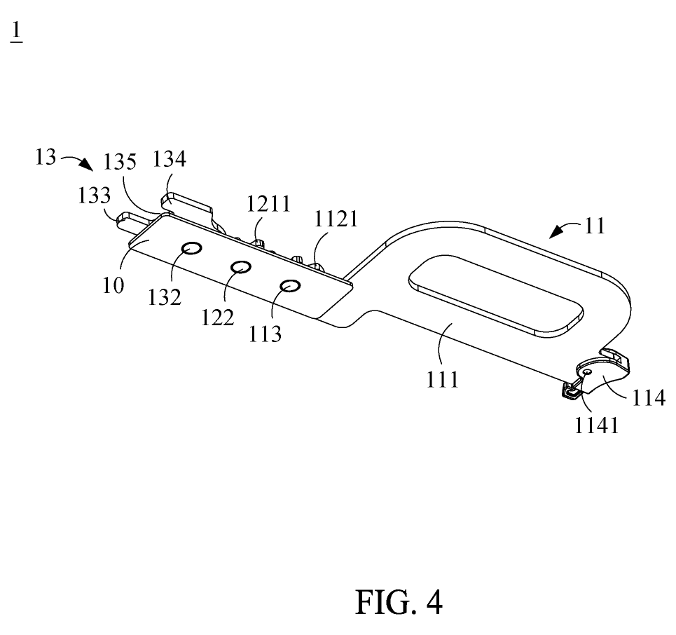

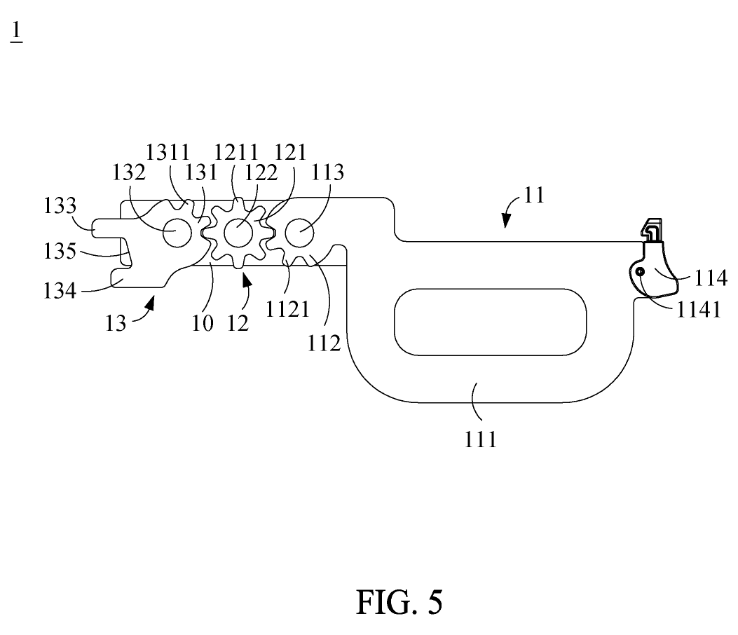

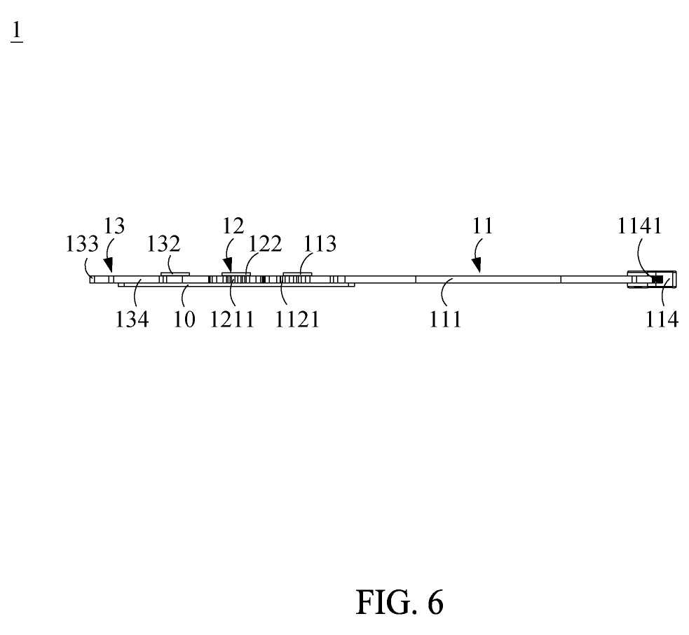

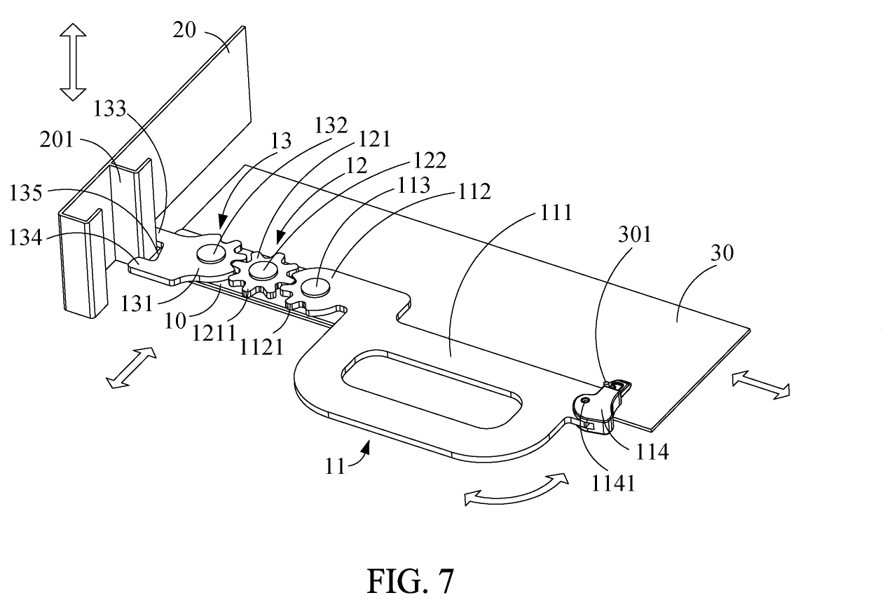

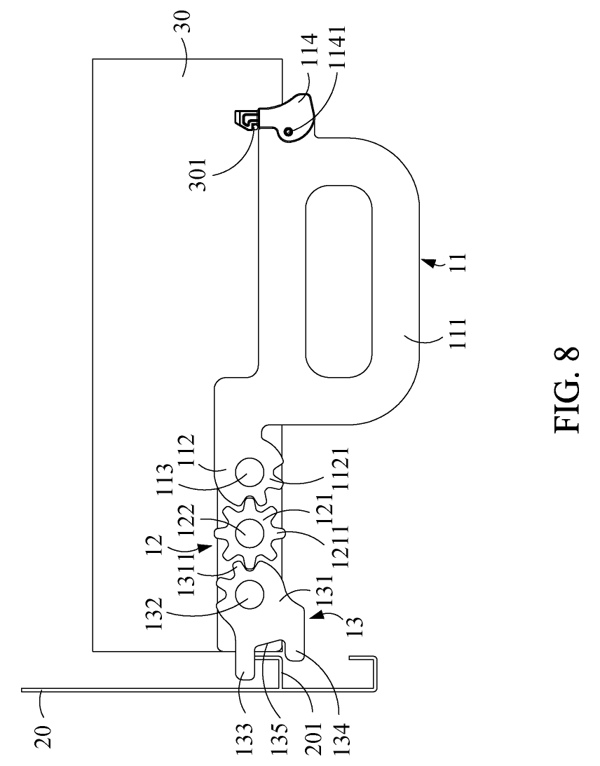

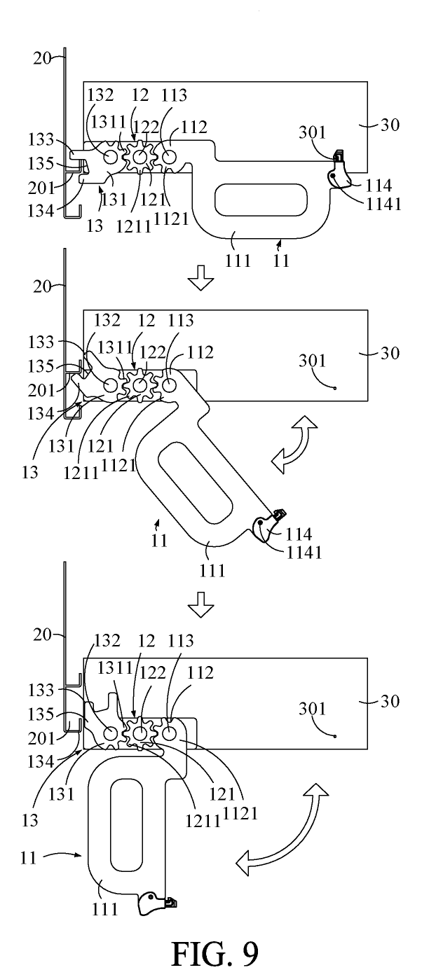

Referring to FIGS. 1 to 9, as shown in the figures, the present disclosure provides a moving structure. The moving structure 1 includes an operating member 11, a transmission member 12, and a moving member 13.

The operating member 11 is movably arranged on a base body 10.

The transmission member 12 is movably arranged on the base body 10 and movably connected to an end of the operating member 11.

The moving member 13 is movably arranged on the base body 10 and has an end movably connected to the transmission member 12. An other end of the moving member 13 is configured to abut and push to be snap-fitted to or unfastened from a corresponding object 20.

In an embodiment of the present disclosure, the base body 10, the operating member 11, the transmission member 12, and the moving member 13 may be assembled with each other to form a module. Alternatively, the base body 10 may be assembled to an object 30, and the base body 10 and the object 30 may be assembled and formed in one piece, or the base body 10 is the object 30. In addition, the corresponding object 20 or the object 30 may be a server casing, a casing, a mainboard, a server rack, a rack, a radiator, a sliding rail, a chip, a connector, a server, or a computer.

During snap-fitting, the moving member 13 abuts and pushes to be snap-fitted to the interlocking portion 201 of the corresponding object 20. When an unfastening operation is performed, a force is applied to the operating member 11, so that the operating member 11 drives the transmission member 12, and the transmission member 12 drives the moving member 13 to move. When the operating member 11 operates to a predetermined angle (for example, 90 degrees), the moving member 13 abuts and pushes to be unfastened from the interlocking portion 201 of the corresponding object 20, so that the moving member 13 can avoid the interlocking portion 201 of the corresponding object 20 when the corresponding object 20 is extracted. In this way, the force may be applied to the operating member 11 to coordinate with the transmission member 12 to drive the moving member 13 to abut and push to be snap-fitted to or unfastened from the corresponding object 20, to complete rapid engagement and disengagement of at least two objects (the corresponding object 20 and the object 30), thereby achieving the objective of repeated rapid engagement and disengagement.

In an embodiment of the present disclosure, the moving member 13 may also be configured to abut and push the corresponding object 20 to drive the object 30 to move, or the moving member 13 is configured to abut and push the corresponding object 20 to drive the object 30 to move in a lever-based labor-saving manner. In this way, the force may also be applied to the operating member 11 to coordinate with the transmission member 12 to drive the moving member 13 to abut and push to be snap-fitted to or unfastened from the corresponding object 20, to complete rapid engagement and disengagement of the at least two objects (the corresponding object 20 and the object 30), thereby achieving the objective of repeated rapid engagement and disengagement.

In an embodiment of the present disclosure, the operating member 11 includes a force application portion 111, a first engaging portion 112, and a first joining portion 113. The first engaging portion 112 is arranged on an end of the force application portion 111. The first engaging portion 112 is movably connected to the transmission member 12 in an engaging manner. The first joining portion 113 is movably arranged on the first engaging portion 112 and is assembled to the base body 10. However, in an embodiment of the present disclosure, the force application portion 111 may be in a form of a grip or a handle, and the first joining portion 113 may be a shaft.

Based on the foregoing embodiments, during snap-fitting, the moving member 13 abuts and pushes to be snap-fitted to the interlocking portion 201 of the corresponding object 20. When an unfastening operation is performed, a force is applied to the force application portion 111 of the operating member 11, so that the operating member 11 rotates by using the first joining portion 113 as a pivot. Because of the rotation, the first engaging portion 112 drives the transmission member 12, and the transmission member 12 drives the moving member 13 to move. When the operating member 11 operates to a predetermined angle (for example, 90 degrees), the moving member 13 abuts and pushes to be unfastened from the interlocking portion 201 of the corresponding object 20, so that the moving member 13 can avoid the interlocking portion 201 of the corresponding object 20 when the corresponding object 20 is extracted. In this way, the force may be applied to the operating member 11 to coordinate with the transmission member 12 to drive the moving member 13 to abut and push to be snap-fitted to or unfastened from the corresponding object 20, to complete rapid engagement and disengagement of at least two objects (the corresponding object 20 and the object 30), thereby achieving the objective of repeated rapid engagement and disengagement.

In addition to the foregoing embodiments, in an embodiment of the present disclosure, unlike the foregoing embodiments, the transmission member 12 includes a second engaging portion 121 and a second joining portion 122. The second joining portion 122 is movably arranged on the second engaging portion 121 and is assembled to the base body 10. The second engaging portion 121 is movably connected to the operating member 11 and the moving member 13 in an engaging manner. However, in an embodiment of the present disclosure, the second joining portion 122 may be a shaft.

Based on the foregoing embodiments, during snap-fitting, the moving member 13 abuts and pushes to be unfastened from the interlocking portion 201 of the corresponding object 20. When the unfastening operation is performed, a force is applied to the force application portion 111 of the operating member 11, so that the operating member 11 rotates by using the first joining portion 113 as a pivot. Because of the rotation, the first engaging portion 112 drives the second engaging portion 121 of the transmission member 12. Therefore, the transmission member 12 is rotated with the second joining portion 122 as a pivot, and further, the transmission member 12 drives the moving member 13 through the second engaging portion 121. When the operating member 11 operates to a predetermined angle (for example, 90 degrees), the moving member 13 abuts and pushes to be unfastened from the interlocking portion 201 of the corresponding object 20, so that the moving member 13 can avoid the interlocking portion 201 of the corresponding object 20 when the corresponding object 20 is extracted. In this way, the force may be applied to the operating member 11 to coordinate with the transmission member 12 to drive the moving member 13 to abut and push to be snap-fitted to or unfastened from the corresponding object 20, to complete rapid engagement and disengagement of at least two objects (the corresponding object 20 and the object 30), thereby achieving the objective of repeated rapid engagement and disengagement.

In addition to the foregoing embodiments, in an embodiment of the present disclosure, unlike the foregoing embodiments, the moving member 13 includes a third engaging portion 131, a third joining portion 132, a first abutting portion 133, a second abutting portion 134, and a snap-fit portion 135. The third engaging portion 131 is arranged on an end of the moving member 13. The third engaging portion 131 is movably connected to the transmission member 12 in an engaging manner. The third joining portion 132 is movably arranged on the third engaging portion 131 and is assembled to the base body 10. The first abutting portion 133 and the second abutting portion 134 are correspondingly arranged on the other end of the moving member 13. The snap-fit portion 135 is located between the first abutting portion 133 and the second abutting portion 134. However, in an embodiment of the present disclosure, the third joining portion 132 may be a shaft.

Based on the foregoing embodiments, during snap-fitting, the moving member 13 pushes against the interlocking portion 201 of the corresponding object 20 through the first abutting portion 133 and the second abutting portion 134 and causes the snap-fit portion 135 to be snap-fitted to the interlocking portion 201, so that the interlocking portion 201 is located between the first abutting portion 133 and the second abutting portion 134. When the unfastening operation is performed, a force is applied to the force application portion 111 of the operating member 11, so that the operating member 11 rotates by using the first joining portion 113 as a pivot. Because of the rotation, the first engaging portion 112 drives the second engaging portion 121 of the transmission member 12. Therefore, the transmission member 12 rotates by using the second joining portion 122 as a pivot. Further, the transmission member 12 drives the third engaging portion 131 of the moving member 13 through the second engaging portion 121 to move the moving member 13. When the operating member 11 operates to a predetermined angle (for example, 90 degrees), the second abutting portion 134 (or the first abutting portion 133) of the moving member 13 pushes against the interlocking portion 201 of the corresponding object 20, and the snap-fit portion 135 is moved away from the interlocking portion 201 for unfastening, so that the first abutting portion 133, the second abutting portion 134, and the snap-fit portion 135 of the moving member 13 can avoid the interlocking portion 201 of the corresponding object 20 when the corresponding object 20 is extracted. In this way, the force may be applied to the operating member 11 to coordinate with the transmission member 12 to drive the moving member 13 to abut and push to be snap-fitted to or unfastened from the corresponding object 20, to complete rapid engagement and disengagement of at least two objects (the corresponding object 20 and the object 30), thereby achieving the objective of repeated rapid engagement and disengagement.

In addition to the foregoing embodiments, in an embodiment of the present disclosure, unlike the foregoing embodiments, the first engaging portion 112 has a plurality of first teeth 1121. The first engaging portion 112 is movably connected to the transmission member 12 through each of the first teeth 1121 in an engaging manner. However, the second engaging portion 121 has a plurality of second teeth 1211. The second engaging portion 121 is movably connected to the operating member 11 and the moving member 13 through each of the second teeth 1211 in an engaging manner. The third engaging portion 131 has a plurality of third teeth 1311. The third engaging portion 131 is movably connected to the transmission member 12 through the third teeth 1311 in an engaging manner. In this way, it may be learned from the foregoing embodiments that, in the present disclosure, the first engaging portion 112 is engaged with each of the second teeth 1211 of the second engaging portion 121 through each of the first teeth 1121, and the third engaging portion 131 is also engaged with each of the second teeth 1211 of the second engaging portion 121 through each of the third teeth 1311.

Based on the foregoing embodiments, during an operation of snap-fitting or unfastening through abutting, the operating member 11 is caused to rotate by using the first joining portion 113 as a pivot. Because of the rotation, the first engaging portion 112 drives each of the second teeth 1211 of the second engaging portion 121 through each of the first teeth 1121, so that the transmission member 12 rotates by using the second joining portion 122 as a pivot. Further, the second engaging portion 121 drives each of the third teeth 1311 of the third engaging portion 131 through each of the second teeth 1211, to move the moving member 13. In this way, the force may be applied to the operating member 11, so that the operating member 11 coordinates with the transmission member 12 to drive the moving member 13 to abut and push to be snap-fitted to or unfastened from the corresponding object 20 to complete rapid engagement and disengagement of at least two objects (the corresponding object 20 and the object 30) in a relatively low-force manner, thereby achieving the objective of repeated rapid engagement and disengagement.

In addition to the foregoing embodiments, in an embodiment of the present disclosure, unlike the foregoing embodiments, the moving member 13 includes a third engaging portion 131, a third joining portion 132, a first abutting portion 133, and a second abutting portion 134. The third engaging portion 131 is arranged on the moving member 13. The third engaging portion 131 is movably connected to the transmission member 12 in an engaging manner to move the moving member 13 through gear transmission, so that the first abutting portion 133 or the second abutting portion 134 abuts against the corresponding object 20 to drive the object 30 to move. In this way, the force may be applied to the operating member 11, so that the operating member 11 coordinates with the transmission member 12 to drive the moving member 13 to abut and push to be snap-fitted to or unfastened from the corresponding object 20 to complete rapid engagement and disengagement of at least two objects (the corresponding object 20 and the object 30) in a relatively low-force manner, thereby achieving the objective of repeated rapid engagement and disengagement.

In addition to the foregoing embodiment, in an embodiment of the present disclosure, unlike the foregoing embodiments, the force application portion 111 of the operating member 11 is provided with a fixing portion 114. The fixing portion 114 is snap-fitted to or unfastened from the limiting portion 301 of the object 30. The fixing portion 114 is movably assembled to the operating member 11 through a bolt 1141. An elastic assembly 1142 is arranged between the force application portion 111 of the operating member 11 and the fixing portion 114. In this way, when the operating member 11 coordinates with the transmission member 12 to drive the moving member 13 to abut and push to be snap-fitted to the corresponding object 20, the moving member may be snap-fitted to the limiting portion 301 of the object 30 through the fixing portion 114 in cooperation with the bolt 1141 and the elastic force of the elastic assembly 1142, so that a safety mechanism is formed to prevent the operating member 11 from being separated, thereby achieving an effect of stable snap-fitting. When abutting and pushing to be unfastened is performed, the fixing portion 114 may be first unfastened from the limiting portion 301, and then the operating member 11 is operated in the foregoing manner to complete rapid engagement and disengagement of at least two objects (the corresponding object 20 and the object 30), thereby achieving the objective of repeated rapid engagement and disengagement.

In addition to the foregoing embodiment, in an embodiment of the present disclosure, unlike the foregoing embodiments, the object 30 may be a server, a computer, or a printed circuit board that is horizontally arranged (or longitudinally arranged). The corresponding object 20 may be a casing, a cabinet, or a column that is longitudinally arranged. Therefore, for the moving structure 1, the moving member 13 abuts and pushes to be snap-fitted to the interlocking portion 201 of the corresponding object 20 during snap-fitting. When the unfastening operation is performed, a force is applied to the operating member 11, so that the operating member 11 drives the transmission member 12, and the transmission member 12 is caused to drive the moving member 13 to move. When the operating member 11 operates to a predetermined angle, the moving member 13 abuts and pushes to be unfastened from the interlocking portion 201 of the corresponding object 20, so that the moving member 13 can avoid the interlocking portion 201 of the corresponding object 20 when the corresponding object 20 is extracted. In this way, the force may be applied to the operating member 11 to coordinate with the transmission member 12 to drive the moving member 13 to abut and push to be snap-fitted to or unfastened from the corresponding object 20, so that the object 30 may be driven to move forward and backward, or to move forward and backward in a horizontal position to complete rapid engagement and disengagement of at least two objects (the corresponding object 20 and the object 30), thereby achieving the objective of repeated rapid engagement and disengagement.

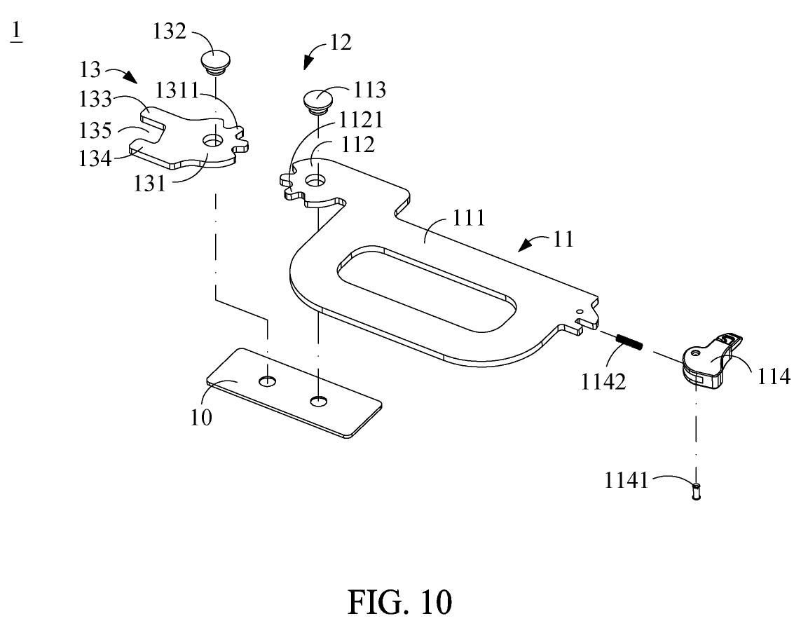

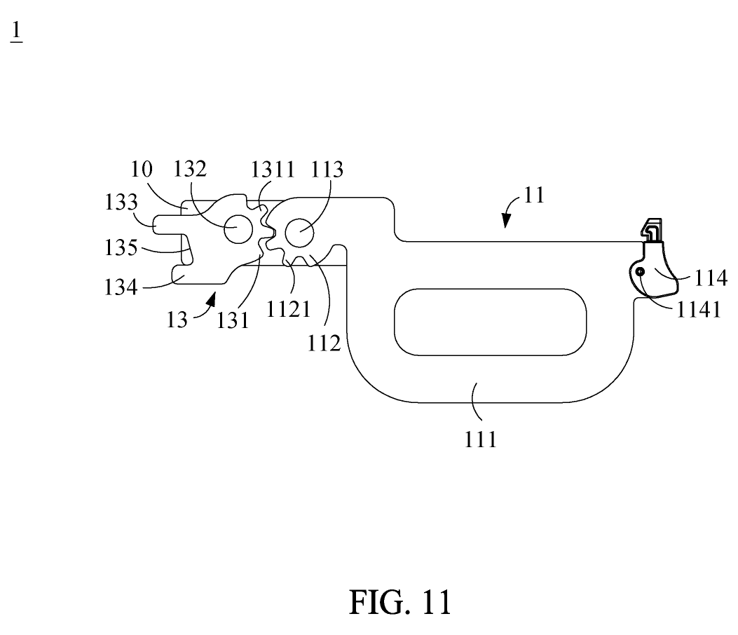

Referring to FIG. 10 and FIG. 11, as shown in the figures, in addition to the foregoing embodiments, in an embodiment of the present disclosure, a difference between the embodiment and the foregoing embodiments lies in that the moving structure 1 includes an operating member 11 and a moving member 13.

The operating member 11 is movably arranged on a base body 10.

The moving member 13 is movably arranged in the base body 10 and has an end movably connected to the operating member 11. The moving member 13 is configured to be snap-fitted to or unfastened from the foregoing corresponding object 20, so that the moving member 13 pushes against the corresponding object 20 to drive the foregoing object 30 to move (for example, movement through leverage).

During snap-fitting, the moving member 13 is snap-fitted to the interlocking portion 201 of the foregoing corresponding object 20. When an unfastening operation is performed, a force is applied to the operating member 11, so that the operating member 11 drives the moving member 13 to move. When the operating member 11 operates to a predetermined angle, the moving member 13 abuts and pushes to be unfastened from the interlocking portion 201 of the corresponding object 20, so that the moving member 13 can avoid the interlocking portion 201 of the corresponding object 20 when the corresponding object 20 is extracted. In this way, the force may be applied to the operating member 11 to coordinate with the transmission member to drive the moving member 13 to abut and push to be snap-fitted to or unfastened from the corresponding object 20, to complete rapid engagement and disengagement of at least two objects (the corresponding object 20 and the object 30), thereby achieving the objective of repeated rapid engagement and disengagement.

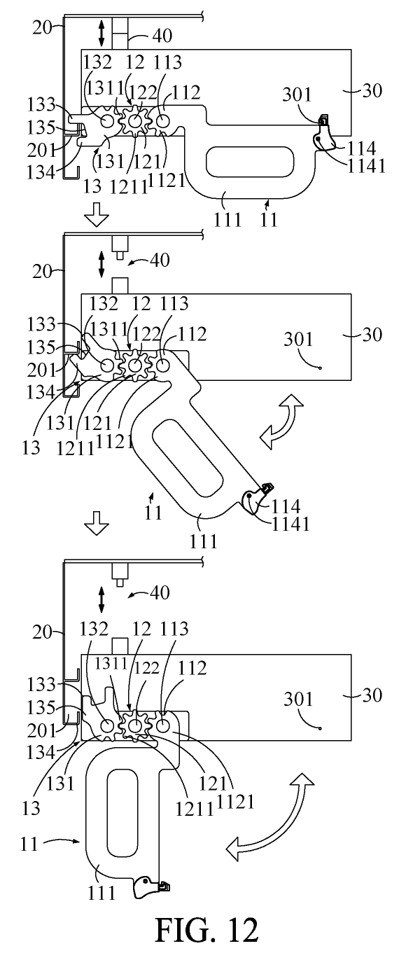

Referring to FIG. 12, as shown in the figure, in addition to the foregoing embodiments, in an embodiment of the present disclosure, a difference between the embodiment and the foregoing embodiments lies in that the moving structure 1 is configured to separate or connect a water cooling joint 40 (which may also be configured to separate or connect a connector or a coolant pipeline). In this way, the force may also be applied to the operating member 11 to coordinate with the transmission member to drive the moving member 13 to abut and push to be snap-fitted to or unfastened from the corresponding object 20, to complete rapid engagement and disengagement of the at least two objects (the corresponding object 20 and the object 30), thereby achieving the objective of repeated rapid engagement and disengagement.

Based on the above, in the moving structure of the present disclosure, the base body may be assembled with the object, and the force is applied to the operating member to coordinate with the transmission member to drive the moving member to abut and push to be snap-fitted to or unfastened from the corresponding object, to complete rapid engagement and disengagement of at least two objects, thereby achieving the effect of repeated rapid engagement and disengagement.

The foregoing are merely embodiments of the present disclosure, and are not intended to limit the scope of the present disclosure.

What is claimed is:

1. A moving structure, comprising:
an operating member, movably arranged on a base body;
a transmission member, movably arranged on the base body and movably connected to the operating member; and
a moving member, movably arranged on the base body and movably connected to the transmission member, or configured to abut and push to be snap-fitted to or unfastened from a corresponding object, or configured to abut and push the corresponding object to drive the object to move, or configured to abut and push the corresponding object to drive the object to move through leverage.

2. The moving structure according to claim 1, wherein the operating member comprises a force application portion, a first engaging portion, or a first joining portion, or the first engaging portion is arranged on the force application portion, or the first engaging portion is movably connected to the transmission member in an engaging manner, or the first joining portion is movably arranged on the first engaging portion and assembled to the base body.

3. The moving structure according to claim 2, wherein the first engaging portion has a plurality of first teeth, or the first engaging portion is movably connected to the transmission member in an engaging manner through each of the first teeth.

4. The moving structure according to claim 1, wherein the operating member is provided with a fixing portion, and the fixing portion is snap-fitted to or unfastened from a limiting portion of the object.

5. The moving structure according to claim 4, wherein the fixing portion is movably assembled to the operating member through a bolt.

6. The moving structure according to claim 4, wherein an elastic assembly is arranged between the fixing portion and the operating member.

7. The moving structure according to claim 1, wherein the transmission member comprises a second engaging portion or a second joining portion, or the second joining portion is movably arranged on the second engaging portion or assembled to the base body, or the second engaging portion is movably connected to the operating member and the moving member in an engaging manner.

8. The moving structure according to claim 7, wherein the second engaging portion has a plurality of second teeth, or the second engaging portion is movably connected to the operating member and the moving member in an engaging manner through each of the second teeth.

9. The moving structure according to claim 1, wherein the moving member comprises a third engaging portion, a third joining portion, a first abutting portion, a second abutting portion, or a snap-fit portion, or the third engaging portion is arranged on the moving member, or the third engaging portion is movably connected to the transmission member in an engaging manner, or the third joining portion is movably arranged on the third engaging portion or assembled to the base body, or the first abutting portion and the second abutting portion are correspondingly arranged on the moving member, or the snap-fit portion is located between the first abutting portion and the second abutting portion.

10. The moving structure according to claim 9, wherein the third engaging portion has a plurality of third teeth, and the third engaging portion is movably connected to the transmission member in an engaging manner through each of the third teeth.

11. The moving structure according to claim 1, wherein the corresponding object or the object is a server casing, a casing, a mainboard, a server rack, a rack, a radiator, a sliding rail, a chip, a connector, a server, or a computer.

12. The moving structure according to claim 1, wherein the moving member comprises a third engaging portion, a third joining portion, a first abutting portion, and a second abutting portion, the third engaging portion is arranged on the moving member, and the third engaging portion is movably connected to the transmission member in an engaging manner to drive the moving member to move through gears, so that the first abutting portion or the second abutting portion abuts against the corresponding object to drive the object to move.

13. The moving structure according to claim 1, wherein the object is a server, a computer, or a printed circuit board that is horizontally arranged, or the corresponding object is a casing, a cabinet, or a column that is longitudinally arranged, so that the moving structure drives the object to move forward and backward, or to move forward and backward in a horizontal position.

14. The moving structure according to claim 1, wherein the object is a server, a computer, or a printed circuit board that is longitudinally arranged, or the corresponding object is a casing, a cabinet, or a column that is longitudinally arranged, so that the moving structure drives the object to move forward and backward, or to move forward and backward in a horizontal position.

15. The moving structure according to claim 1, wherein the moving structure is configured to separate or connect a water cooling joint, a connector, or a coolant pipeline.

16. A moving structure, comprising:
an operating member, movably arranged on a base body; and
a moving member, movably arranged on the base body and movably connected to the operating member, or configured to abut and push to be snap-fitted to or unfastened from a corresponding object, or configured to abut and push the corresponding object to drive the object to move, or configured to abut and push the corresponding object to drive the object to move through leverage.

17. The moving structure according to claim 16, wherein the moving structure is configured to separate or connect a water cooling joint, a connector, or a coolant pipeline.

18. The moving structure according to claim 16, wherein the object is a server, a computer, or a printed circuit board that is horizontally arranged, or the corresponding object is a casing, a cabinet, or a column that is longitudinally arranged, so that the moving structure drives the object to move forward and backward, or to move forward and backward in a horizontal position.

19. The moving structure according to claim 16, wherein the object is a server, a computer, or a printed circuit board that is longitudinally arranged, or the corresponding object is a casing, a cabinet, or a column that is longitudinally arranged, so that the moving structure drives the object to move forward and backward, or to move forward and backward in a horizontal position.

20. The moving structure according to claim 16, wherein the operating member comprises a force application portion, a first engaging portion, or a first joining portion, or the first engaging portion is arranged on the force application portion, or the first engaging portion is movably connected to the moving member in an engaging manner or through an engagement structure, or the first joining portion is movably arranged on the first engaging portion and assembled to the base body.
